(19) United States
(12) Patent Application Publication
(10) Pub. No.: US 2009/0186293 A1
(43) Pub. Date: Jul. 23, 2009

(54) DRY FILM PROTORESIST FOR A MICRO-FLUID EJECTION HEAD AND METHOD THEREFOR

(76) Inventors: Bryan Thomas Fannin, Versailles, KY (US); David Christopher Graham, Lexington, KY (US); Sean Terrance Weaver, Union, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(21) Appl. No.: 12/018,433

(22) Filed: Jan. 23, 2008

(51) Int. Cl. G03F 7/004; G03F 7/26

(52) U.S. Cl. 430/270.1; 430/320

(57) ABSTRACT

A method for making a dry film photoresist layer for a micro-fluid ejection head and a micro-fluid ejection head made by the method. The method includes applying a photoimageable liquid to a moving web of release material to provide a photoimageable layer on the release material using a slot die coater. The layer on the release material has a coating thickness ranging from about 8 to about 25 microns with a thickness variation of no more than about one micron. The photoimageable layer on the web is dried to provide a dry film photoresist layer. A protective web is then applied to the dry film photoresist layer.

### TECHNICAL FIELD

The disclosure relates to micro-fluid ejection heads, and in particular to improved dry film photoresist materials for laminating to a micro-fluid ejection head structure to provide a substantially planarized, relatively thin photoresist film on the structure.

### BACKGROUND AND SUMMARY

Micro-fluid ejection heads are useful for ejecting a variety of fluids including inks, cooling fluids, pharmaceuticals, lubricants and the like. A widely used micro-fluid ejection head is in an ink jet printer. Ink jet printers continue to be improved as the technology for making the micro-fluid ejection heads continues to advance. New techniques are constantly being developed to provide low cost, highly reliable printers which approach the speed and quality of laser printers. An added benefit of ink jet printers is that color images can be produced at a fraction of the cost of laser printers with as good or better quality than laser printers. All of the foregoing benefits exhibited by ink jet printers have also increased the competitiveness of suppliers to provide comparable printers in a more cost efficient manner than their competitors.

One area of improvement in the printers is in the print engine or micro-fluid ejection head itself. This seemingly simple device is a relatively complicated structure containing electrical circuits, ink passageways and a variety of tiny parts assembled with precision to provide a powerful, yet versatile micro-fluid ejection head. The components of the ejection head must cooperate with each other and with a variety of fluid formulations to provide the desired ejected fluid properties. Accordingly, it is important to match the ejection head components to the fluid and the duty cycle demanded by the ejection device. Slight variations in production quality can have a tremendous influence on the product yield and resulting fluid ejector performance.

In order to improve the quality of the micro-fluid ejection heads, new techniques for assembling components of the heads are being developed. For example, instead of separately forming nozzle holes in a metal or polyimide nozzle plate material that is then adhesively attached to a semiconductor substrate structure, a dry film photoimageable material may be laminated to an imaged and developed thick film layer made of similar materials on the semiconductor substrate.

An advantage of a dry film lamination method for constructing micro-fluid ejection heads is that wafer level processing of multiple ejection heads may be conducted simultaneously rather than assembling individual components to individual ejection head substrates. The material to be laminated to the thick film layer on a substrate to provide the nozzle plate layer is produced in a separate process and then laminated with pressure and/or heat to the thick film layer. However, variations in the thickness, smoothness, and uniformity of the nozzle plate laminate material makes further processing of the nozzle plate difficult and may result in low yields of acceptable micro-fluid ejection head structures.

Accordingly, what are needed are an improved dry film photoresist laminate material and an improved process for making the dry film laminate material to provide more uniform nozzle plate layers.

In view of the foregoing, exemplary embodiments of the disclosure provide a method for making a dry film photoresist layer for a micro-fluid ejection head and a micro-fluid ejection head made by the method. The method includes applying a photoimageable liquid to a moving web of release material to provide a photoimageable layer on the release material using a slot die coater. The layer on the release material has a coating thickness ranging from about 2 to about 50 microns with a thickness variation of no more than about one micron. The photoimageable layer on the web is dried to provide a dry film photoresist layer. A protective web is then applied to the dry film photoresist layer.

In another embodiment, there is provided a method of making a micro-fluid ejection head having a photoimageable nozzle plate. The method includes applying a photoimageable thick film layer to a device surface of a substrate having fluid ejection actuators thereon. The thick film layer is imaged and developed to provide fluid flow features therein. A photoimageable nozzle plate dry film layer made by a slot die coating method is applied to the imaged and developed thick film layer. The dry film layer is imaged and developed to provide nozzles therein for ejection of fluid therethrough.

An advantage of the embodiments described herein is that the dry film photoimageable layer used for the nozzle plate has an essentially uniform thickness and is substantially devoid of air bubbles, streaks, and/or grooves. An exposed surface of the photoimageable layer on the substrate structure may have a surface roughness (Ra) value of less than about 20 nanometers and a maximum peak to value (Rt) value of less than about 1 micron. Since the slot die coating method applies liquid under substantially constant pressure to a moving web from a closed pressure container, air entrapment in the liquid that may cause the air bubbles is avoided. Another advantage of the slot die coating method over conventional coating methods is that evaporation of liquid components of the photoimageable liquid material is minimized. Accordingly, an essentially consistent solids content of the photoimageable liquid material may be maintained during the coating process thereby enabling improved planarity of the coated layer.

### BRIEF DESCRIPTION OF THE DRAWINGS

Further features and advantages of the disclosed embodiments may become apparent by reference to the detailed description when considered in conjunction with the figures, which are not to scale, wherein like reference numbers indicate like elements through the several views, and wherein:

FIGS. 1 and 2 are schematic illustrations of prior art web coating methods for making dry film photoimageable materials;

FIG. 3 is a schematic illustration of a slot die coating method for making a photoimageable dry film layer according to the disclosure;

FIG. 4 is an enlarged view, not to scale, of a photoimageable dry film layer on a prior art release backing web and having a protective web applied thereto;

FIG. 5 is a cross-sectional view, not to scale, of an ejection head structure containing a photoimageable layer made using a prior art backing material.

FIG. 6 is an enlarged view, not to scale, of a photoimageable dry film layer and a protective web on a release backing web according to an embodiment of the disclosure;

FIG. 7 is a cross-sectional view, not to scale, of the photoimageable dry film layer of FIG. 6 after removing the protective web;

FIGS. 8-13 illustrate a method for making a micro-fluid ejection head according to an embodiment of the disclosure;

FIG. 14 is a plan view, not a micro-fluid ejection head made according to an embodiment of the disclosure;

FIG. 15 is a perspective view, not to scale, of a fluid reservoir containing a micro-fluid ejection head according to the disclosure; and

FIG. 16 is a perspective view, not to scale of a micro-fluid ejection device for ejecting fluid from an ejection head made according to the disclosure.

### DETAILED DESCRIPTION OF THE PREFERRED EMBODIMENTS

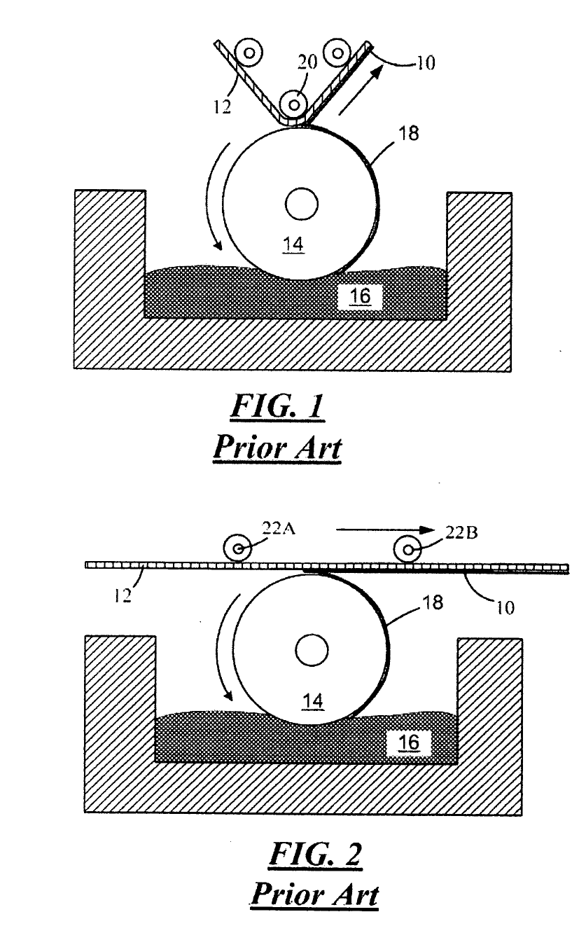

As set forth above, improved micro-fluid ejection heads may include nozzle members having a substantially uniform thickness that are substantially devoid of air bubbles, streaks, and/or grooves. Conventional processes used to provide dry film photoimageable layers include rotogravure techniques as illustrated in FIGS. 1 and 2. In a first prior art technique, a photoimageable layer 10 is applied to a moving web of backing material 12 using an elongate engraved roll 14 that rotates in a pool 16 of liquid photoresist material. As the roll 14 rotates, a thin film 18 of the photoresist material is captured in grooves on the roll and is applied to the moving web 12 that is kept in contact with the roll 14 by a back up roller 20. In FIG. 2, an off-roller gravure coating method is illustrated wherein two rollers 22A and 22B are offset from the roll 14 for maintaining the web 12 in contact with the grooved roll 14. In both FIGS. 1 and 2, the thin film 18 on the roll 14 is applied to the moving web 12 to provide the photoimageable layer 10. The layer 10 is then dried to form a dry film photoresist layer on the backing material 12.

However, the dry film photoresist layer made by the foregoing method has significant shortfalls that make it unsuitable for use in making photoimageable nozzle plates. For one, the dry film layer may contain streaks or lines caused by the grooves in the roll 14 used to apply the thin film 18 to the backing material 12. Also, the liquid photoresist material in the pool 16 is often exposed to the environment during the coating process. Accordingly, evaporation of liquid components of the composition provides an ever changing solids concentration in the pool 16 of liquid. Because the solids concentration is changing, coating thicknesses may fluctuate significantly causing unwanted variations in dry film thickness.

Another disadvantage of the coating methods described above with reference to FIGS. 1 and 2 is that the roll 14 is constantly churning the pool 16 of liquid entrapping unwanted air bubbles in the pool 16 of liquid. Upon curing, the dry film layer may contain air pockets which may affect imaging resolution and thus nozzle tolerances required for micro-fluid ejection heads.

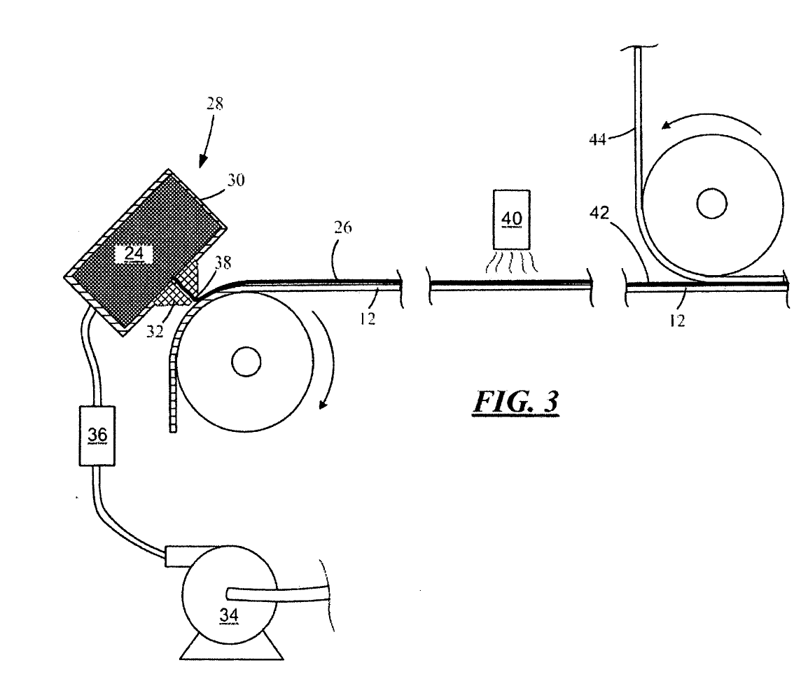

In order to overcome the disadvantages of the conventional roll coating methods illustrated in FIGS. 1 and 2, a slot die coating method for applying a liquid photoresist composition 24 to the backing web 12 to provide a photoimageable layer 26 on the backing web 12 is illustrated schematically in FIG. 3. The liquid photoresist composition 24 is provided to a slot die coater 28 including a closed pressure vessel 30 containing a die outlet 32. The composition 24 is provided to the pressure vessel 30 by a positive displacement pump 34. A filter 36 may be included between the pump 34 and the pressure vessel 30 in order to minimize contamination of the composition 24. The slot die outlet 32 includes a die or outlet port 38 having a height of from about 10 μm to about 200 μm and a length of from about 10 cm to about 75 cm to provide the photoimageable layer 26 on the backing web 12 having a thickness ranging from about 8 to about 25 microns with a thickness variation of no more than about one micron. The slot die coater 28 provides the photoimageable layer 26 on the backing web 12 moving at a rate of about 3 to about 50 meters per minute.

A suitable liquid photoresist composition 24 includes a difunctional epoxy resin, a multi-functional epoxy resin, and a phenoxy resin, wherein the difunctional epoxy resin contains two epoxy groups and the multi-functional epoxy resin contains more than two epoxy groups. The resin components are provided in a solvent for liquid application to the backing web 12. A particularly suitable formulation for the liquid photoresist composition 24 is set forth in the following table.

TABLE 1

| Component | Weight Percent |
|---|---|
| Resin components | 41.6 |
| Solvent | 34.0 |
| Photoinitiator catalyst | 22.2 |
| Optional adhesion enhancing agent | 2.2 |

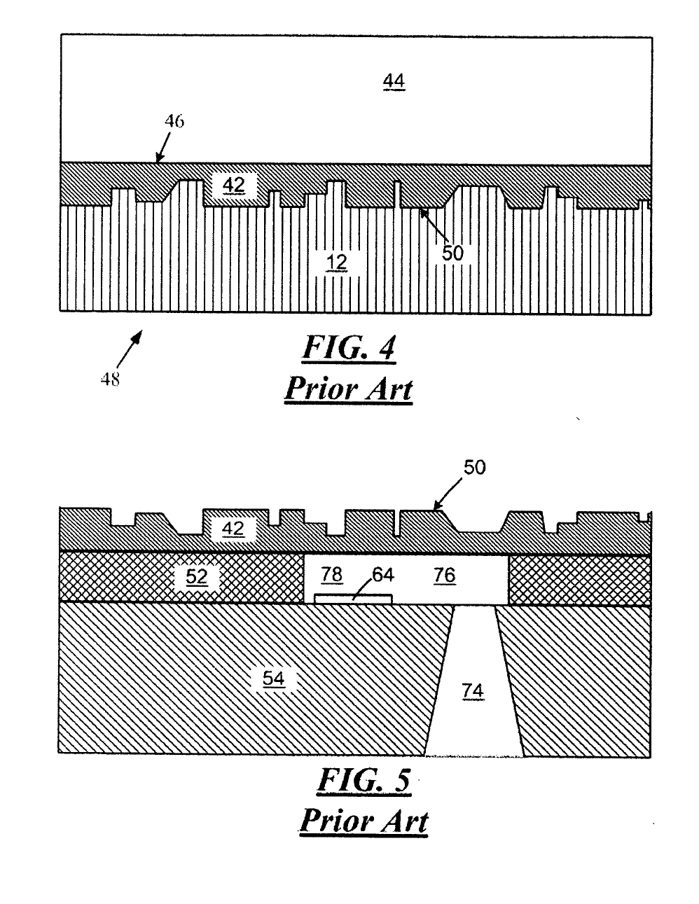

As described above, the photoimageable layer 26 is applied to the backing web 12 by the slot die coater 28 and the layer 26 is then dried with heat from a heat source 40 at a temperature ranging from about 110° to about 150° C., typically about 130° to provide a dried photoimageable layer 42. A protective web layer 44 having a thickness ranging from about 25 μm to about 250 μm is then applied by a lamination process to a surface 46 of the dried photoimageable layer 42 to provide a composite structure 48 illustrated in FIG. 4.

A comparison of the properties of 14 micron thick photoimageable layers made by the prior art coating processes and the slot die process described above is provided in Table 2.

TABLE 2

| | | Percent of air bubbles in |
|---|---|---|
| Process | Thickness variation (μm) | 6 inch diameter layer |
| FIG. 1 | 1.7 | >30 |
| FIG. 2 | 1.5 | >10 |
| FIG. 3 | <0.8 | <1 |

As shown by the foregoing table, the photoimageable layer 42 made by the slot die coating process is substantially more uniform in thickness and contains fewer air bubbles than photoimageable layers made by the prior art coating processes.

Suitable backing web 12 materials may be selected from a wide variety of flexible resilient films such as organic polymer films and metal foils, or a combination thereof that are commonly used as carrier sheet web materials. Accordingly, the backing web 12 may be selected from polyester films, polyimide films, copper clad polyimide films, copper, aluminum, nickel, brass, or stainless steel foils, and the like. Other useable web materials include polyethylene naphthalate (PEN), polyvinyl chloride (PVC), polymethylmethacrylate (PMMA), and polycarbonate films. A particularly suitable backing web 12 may be selected from oriented polyethylene terephthalate (PET) films and polybutylene terephthalate (PBT) films having a thickness ranging from about 25 to about 250 microns.

However, conventional backing materials 12 to which the layer 42 is applied may have unacceptable surface roughness values that may impart an undesirable surface roughness characteristic to the layer 42. As shown in FIG. 4, the backing material 12 is a conventional polyester release material that may have a surface roughness (Ra) value of about 60 to 70 nanometers and a maximum peak to valley (Rt) value of greater than about 1 microns. Since the layer 42 is applied to the backing material 12 as a flowable liquid 26, the layer 42 may conform to the backing material 12 providing a surface 50 of the layer 10 having substantially the same Ra and Rt values as the backing material 12. Accordingly, when the composite structure 48 is applied to a thick film layer 52 on a substrate 54 as shown in FIG. 5, and the backing material 12 removed from the layer 42, surface 50 of the layer 42 is exposed.

The roughness of surface 50, illustrated in FIG. 5 may result in difficulty in cleanly and easily removing the backing material 12 from the layer 42. Such a rough surface 50 may cause inaccuracies when the layer 42 is imaged resulting in irregularly shaped nozzles that may cause misdirection of fluid ejected from the nozzles. The rough surface 50 may also cause undesirable pooling of fluids on the surface 50 that may affect ejected fluid trajectories.

A characteristic of the backing web 12 is that it has a surface that is wettable with the photoimageable layer 42, but is easily released from the photoimageable layer 42 when the photoimageable layer 42 is applied to a micro-fluid ejection head structure. Another characteristic of the backing web 12 is that it provide a relatively smooth surface for application of the photoimageable layer 42 thereto so that an exposed surface 50 of the photoimageable layer 42 on the thick film layer 52 is relatively smooth.

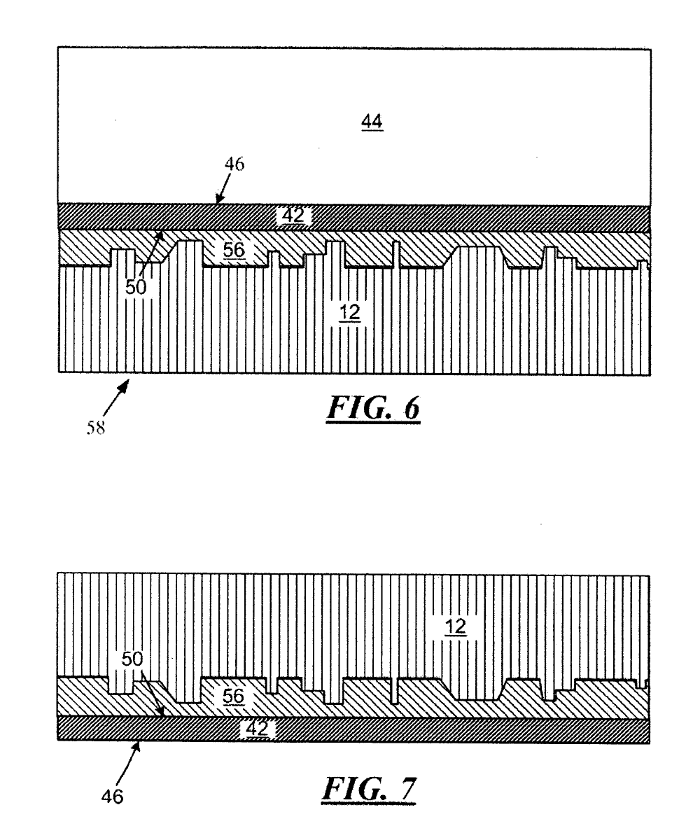

In order to improve the smoothness of an exposed surface 50 of the photoimageable layer 42, a conformal release layer 56 may be interposed between the backing web 12 and the photoimageable layer 42 to provide a composite structure 58 as illustrated in FIG. 6. The conformal release layer 56 may be selected from silicone release layers, acrylate release layers, fluorocarbon release layers and the like. A particularly suitable release layer 56 is urethane acrylic/silicone hybrid cured release coating commercially available from Dainichiseika Color & Chemicals Mfg. Co., Ltd. of Tokyo, Japan, under the trade name SEIKABEAM EXY-10(NS), having a thickness ranging from about 20 to about 100 nanometers, typically about 50 nanometers. The release layer 56 may be applied to the backing material 12 by a wide variety of conventional web coating techniques including, but not limited to, rotogravure coating, blade coating, spray coating, screen printing, and the like. One suitable method for applying the conformal release coating to the backing material 12 may be a microgravure coating method. The backing web material 12 to which the release layer 56 is applied may be corona treated on at least a surface to which the release layer 56 is applied to improve adhesion between the release layer 56 and the backing material 12.

Upon removal of the backing material 12 and release layer 56 from the photoimageable layer 42, the layer has a surface 50 that may have a surface roughness (Ra) value of less than about 20 nanometers and a maximum peak to valley (Rt) value of less than 1 micron. A comparison of the smoothness properties of backing materials made with and without the conformal release layer 56 is provided in Table 3.

TABLE 3

| | Surface Roughness | | Maximum Peak to |
|---|---|---|---|
| | (Ra) value of | | Valley (Rt) value of |
| | photoimageable | | photoimageable |
| Composite materials | layer | | layer |
| Prior art PET release liner 1 | 68.28 | nm | 1.39μ |
| PET release liner w/o layer 56 | 63.88 | nm | 1.67μ |
| PET release liner with | 10 to 19 | nm | 0.49μ |
| layer 56 | | | |

As indicated by the foregoing table, a release liner containing the conformal release layer 56 had significantly lower Ra and Rt values than conventional backing materials. Accordingly, the photoimageable layer 42 applied to the backing material 12 containing the conformal release layer 56 is expected to have much lower Ra and Rt values. The surface 50 of the photoimageable layers 42 having roughness values (Ra) of less than 20 nanometers and maximum peak to valley (Rt) values of less than one micron is defined herein as an “ultra-smooth” surface 50. The ultra-smooth surface 50 of the photoimageable layer 42 may enhance image resolution during an imaging step to form nozzles in the photoimageable layer 42. Also the ultra-smooth surface 50 may reduce flooding potential for fluids on the surface 50 and may decrease mechanical adhesion between the backing material 12 and the photoimageable layer 42, making peeling of the backing material 12 from the photoimageable layer 42 easier. A comparison of peel strengths of coated and uncoated PET films is provided in the following table. Each peel test consisted of five strips of tape having a width of 25 mm and a length of 100 mm attached to uncoated and release layer coated PET film strips.

TABLE 4

| | Avg. 90° Peel Test |
|---|---|
| Test Sample Information | at 50 mm/min for 10 mm |
| PET without a release liner 56 | 591.4 gram-force |
| No. 1 PET with release liner 56 | 407.9 gram-force |
| No. 2 PET with release liner 56 | 387.5 gram-force |
| No. 3 PET with release liner 56 | 367.1 gram-force |
| No. 4 PET with release liner 56 | 377.3 gram-force |
| No. 5 PET with release liner 56 | 418.1 gram-force |
| No. 6 PET with release liner 56 | 356.9 gram-force |
| No. 7 PET with release liner 56 | 377.3 gram-force |
| No. 8 PET with release liner 56 | 377.3 gram-force |

Accordingly, the average peel strength of the release layer coated PET film ranged from about 356.0 gram-force to about 418.1 gram-force compared to the uncoated PET film having a peel strength of 591.4 gram-force.

As described above, the composite material 58 also includes the protective web layer 44. The protective web layer 44 is provided as an interleaf layer on the dried photoimageable layer 42 to enable the composite material 58 to be coiled onto a roll or handled without damaging the surfaces 46 and 50 of the photoimageable layer 42. Upon use of the composite material 58, the protective web layer 44 is removed from the photoimageable layer 42 so that surface 46 is exposed as shown in FIG. 7. A suitable protective web layer 44 may be selected from polymeric films such as polyethylene and polypropylene films that exhibit low surface energy to minimize surface interaction with the photoimageable layer 42. The thickness of the protective web layer 44 is not critical to the disclosed embodiments, provided the protective web layer 44 is thin enough to be substantially flexible. Accordingly, thicknesses of the protective web layer 44 in the range of from about 25 μm to about 250 μm are typical.

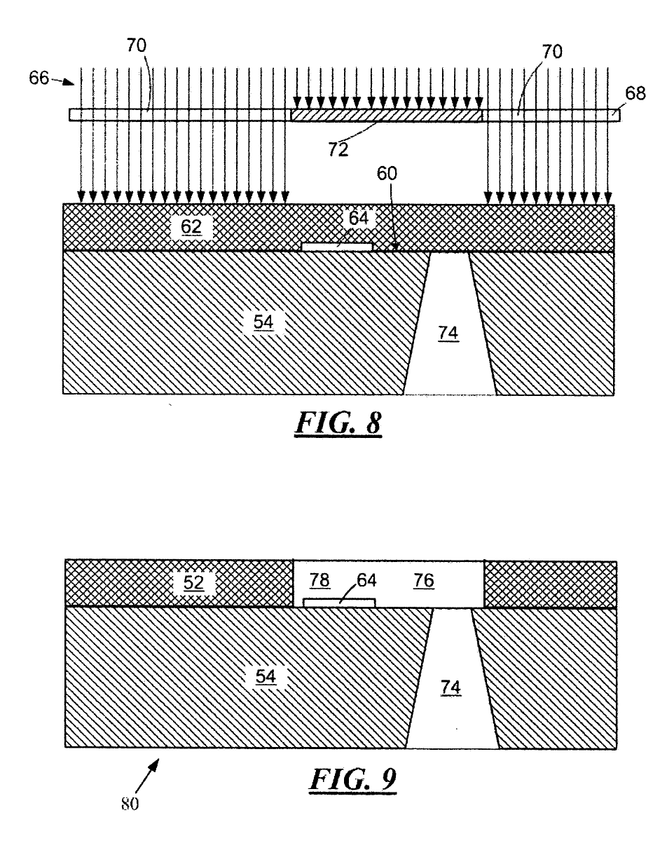

With reference now to FIGS. 8-13, a method for making a micro-fluid ejection head according to an embodiment of the disclosure will now be described. As an initial step in the process of constructing a micro-fluid ejection head, a first photoimageable material is applied to a device surface 60 of a wafer containing a plurality of individual substrates 54 to provide a thick film layer 62 on the substrates 54 as shown in FIG. 8. Each of the substrates 54 is relatively small in size and typically has overall dimensions ranging from about 2 to about 10 millimeters wide by about 10 to about 25 millimeters long and from about 0.4 to about 0.8 mm thick. The substrates 54 may be silicon, ceramic, or other substrate wafer material containing a plurality of fluid ejection actuators such as piezoelectric devices or heater resistors 64 formed on the device surface 60 of the wafer containing the substrates 54. The heater resistors 64 may be formed on the device surface 60 by well known semiconductor manufacturing techniques. In addition to the heater resistors 54, the device surface 60 may include active and passive logic devices, heater selection circuits, and insulative, conductive, and resistive layers.

The device surface 60 of the substrates 54 also contains electrical tracing from the heater resistors 64 to contact pads used for connecting the substrates 54 to a flexible circuit or a tape automated bonding (TAB) circuit for supplying electrical impulses from a fluid ejection controller to activate one or more of the heater resistors 64.

The thick film layer 62 may be provided by a positive or negative photoresist material applied to the wafer as a wet layer by a spin coating process, a spray coating process, or the like. In the alternative the thick film layer 62 may be applied to the wafer as a dry film photoresist material using heat and pressure. Examples of suitable photoresist materials, include, but are not limited to, acrylic and epoxy-based photoresists such as the photoresist materials available from Shell Chemical Company of Houston, Tex. under the trade name EPON SU8 and photoresist materials available from Olin Hunt Specialty Products, Inc. which is a subsidiary of the Olin Corporation of West Paterson, N.J. under the trade name WAYCOAT. Other suitable photoresist materials include the photoresist materials available from Clariant Corporation of Somerville, N.J. under the trade names AZ4620 and AZ1512. A particularly suitable photoresist material includes from about 10 to about 20 percent by weight difunctional epoxy compound, less than about 4.5 percent by weight multifunctional crosslinking epoxy compound, from about 1 to about 10 percent by weight photoinitiator capable of generating a cation, and from about 20 to about 90 percent by weight non-photoreactive solvent as described in U.S. Pat. No. 5,907,333 to Patil et al., the disclosure of which is incorporated by reference herein as if fully set forth.

After coating the thick film layer 62 onto device surface 60 of the substrates 54, flow features may then be formed in the thick film layer 62 using conventional photoimaging techniques such as ultraviolet radiation, indicated by arrows 66 with wavelengths typically in the range of from about 193 to about 450 nanometers. A mask 68 having transparent areas 70 and opaque areas 72 may be used to define the flow features in the thick film layer 62. The imaged thick film layer 62 may be developed using standard photolithographic developing techniques.

Before or after applying the thick film layer 62 to the wafer containing the substrates 54 and before or after imaging and developing the thick film layer 62, one or more fluid supply slots 74 may be formed through the substrates 54 as shown in FIG. 8. The fluid supply slots 74 typically have dimensions of about 9.7 millimeters long and 0.39 millimeters wide. Techniques used for forming the slots 74 may be selected from wet and dry etch techniques or mechanical techniques such as grit blast.

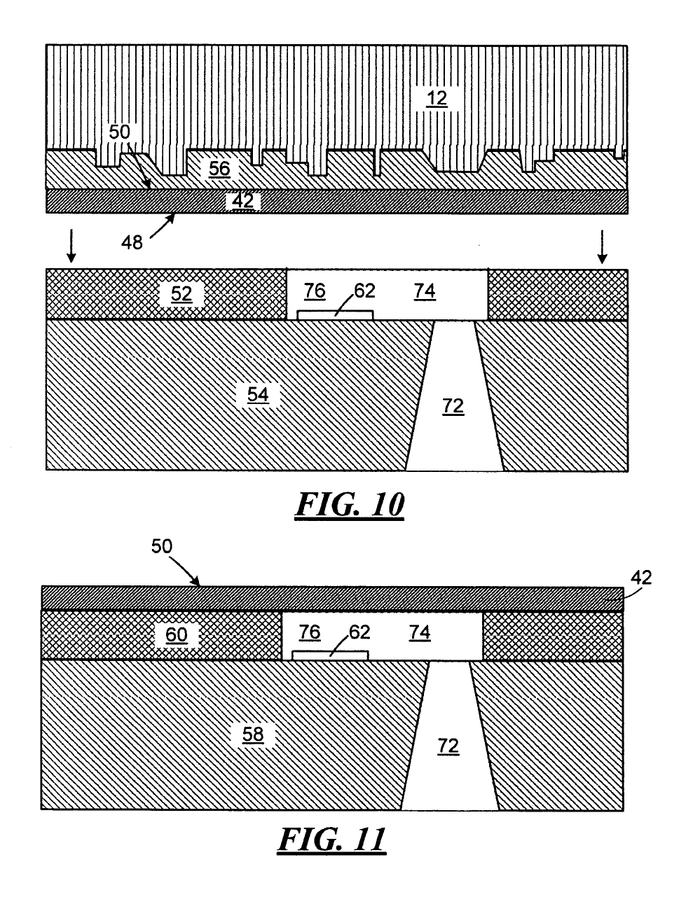

Once developed, the thick film layer 52 may contain fluid supply channels, such as supply channel 76 in flow communication with the slot 74 to provide fluid to fluid ejection chambers, such as ejection chamber 78 as shown in FIG. 9. There is typically one ejection chamber 78 and one fluid supply channel 76 for each fluid ejection actuator 64.

The resulting composite substrate/thick film layer 54/52 is referred to herein as a micro-fluid ejection head structure 80. Next, as shown in FIG. 10, the photoimageable layer 42, after removal of the protective web layer 44, is applied to the imaged and developed thick film layer 52 by a lamination technique. The lamination technique may include heat and pressure to fixedly attach the photoimageable layer 42 to the thick film layer 52. For example, lamination of the photoimageable layer 42 to the structure 80 may be effected using heat and/or pressure in a single or double roll laminator or in a vacuum laminator. Desirable temperature and pressure conditions for laminating the photoimageable layer 42 to the thick film layer 52 may be in the range of from about 30° to about 150° C. and from about 5 to about 80 psig. After attaching the photoimageable layer 42 to the thick film layer 52, the backing web 12 containing the release layer 56 is removed from the photoimageable layer 42.

Nozzles are formed in the photoimageable layer 42 using a photo imaging technique similar to the technique described above with respect to imaging the thick film layer 62. Accordingly, ultraviolet radiation indicated by arrow 82 and a mask 84 containing an opaque area 86 and transparent areas 88 is used to form the nozzles in the photoimageable layer 42. After imaging the photoimageable layer 42, a suitable solvent is used to dissolve the non-imaged areas providing a nozzle plate 90 containing nozzles 92 as shown in FIG. 8.

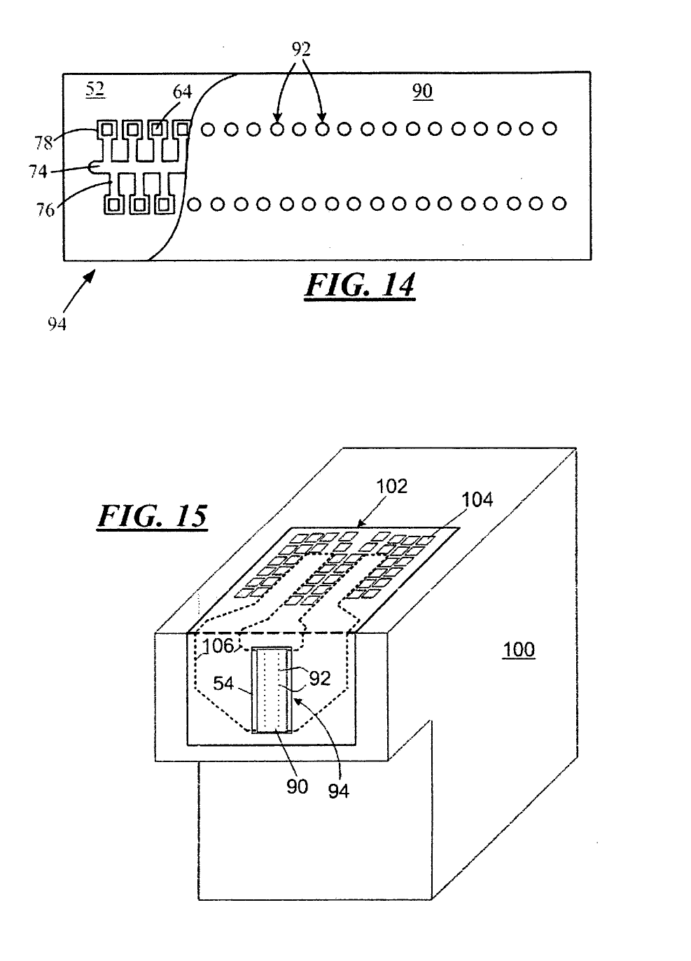

Individual ejection heads 94 may be excised from the wafer containing a plurality of ejection heads 94 to provide the ejection head illustrated in plan view in FIG. 14. Upon activation of the heater resistors 64, fluid supplied through the slot 74 in the substrate 54 through the channels 76 to the chambers 78 is caused to be ejected through nozzles 92 in the nozzle plate 90 toward a medium.

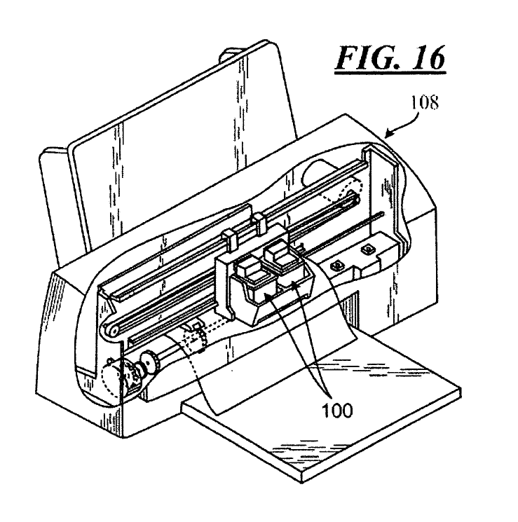

The micro-fluid ejection head 94 may be attached in a well known manner to a chip pocket in a cartridge body to form micro-fluid ejection cartridge 100 as shown in FIG. 15. Fluid to be ejected is supplied to the micro-fluid ejection head 94 from a fluid reservoir in the cartridge body generally opposite the chip pocket. In an alternative, a remote fluid supply may be used to provide fluid to be ejected by the micro-fluid ejection head 94.

The cartridge body of the cartridge 100 may be made of a metal or a polymeric material selected from the group consisting of amorphous thermoplastic polyetherimide available from G.E. Plastics of Huntersville, N.C. under the trade name ULTEM 1010, glass filled thermoplastic polyethylene terephthalate resin available from E. I. du Pont de Nemours and Company of Wilmington, Del. under the trade name RYNITE, syndiotactic polystyrene containing glass fiber available from Dow Chemical Company of Midland, Mich. under the trade name QUESTRA, polyphenylene oxide/high impact polystyrene resin blend available from G.E. Plastics under the trade names NORYL SE1 and polyamide/polyphenylene ether resin available from G.E. Plastics under the trade name NORYL GTX. A suitable polymeric material for making the cartridge body is NORYL SE1 polymer.

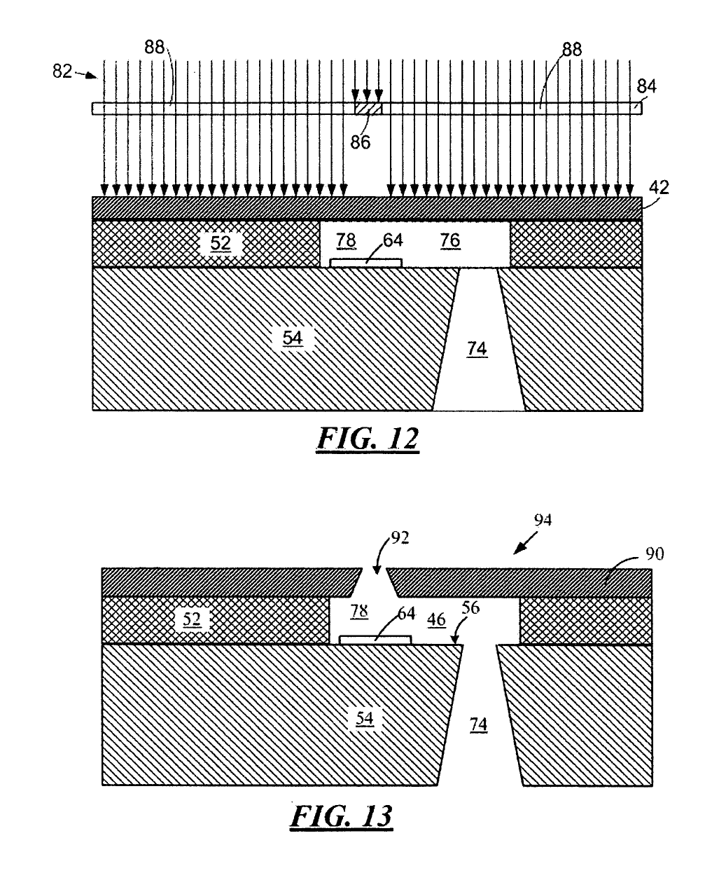

As shown in FIG. 15, a flexible circuit 102 may be attached to the cartridge 100 to provide electrical impulses from contacts 104 through electrical tracing 106 to the ejection head 94. One or more cartridges 100 containing the ejection head 94 may be used in a micro-fluid ejection device 108, such as an ink jet printer as shown in FIG. 11 to provide control and ejection of fluid from the ejection head 94.

At numerous places throughout this specification, reference has been made to a number of U.S. patents. All such cited documents are expressly incorporated in full into this disclosure as if fully set forth herein.

Other embodiments of the present disclosure will be apparent to those skilled in the art from consideration of the specification and practice of the embodiments disclosed herein. As used throughout the specification and claims, “a” and/or “an” may refer to one or more than one. Unless otherwise indicated, all numbers expressing quantities of ingredients, properties such as molecular weight, percent, ratio, reaction conditions, and so forth used in the specification and claims are to be understood as being modified in all instances by the term “about.” Accordingly, unless indicated to the contrary, the numerical parameters set forth in the specification and claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. It is intended that the specification and examples be considered as exemplary only, with a true scope and spirit of the invention being indicated by the following claims.

The patentees do not intend to dedicate any disclosed embodiments to the public, and to the extent any disclosed modifications or alterations may not literally fall within the scope of the claims, they are considered to be part hereof under the doctrine of equivalents.

What is claimed is:

1. A method for making a dry film photoresist layer for a micro-fluid ejection head, comprising:
applying a photoimageable liquid to a moving web of release material to provide a photoimageable layer on the release material using a slot die coater, wherein the layer on the release material has a coating thickness ranging from about 8 to about 25 microns with a thickness variation of no more than about one micron;
drying the photoimageable layer on the web to provide a dry film photoresist layer; and
applying a protective web to the dry film photoresist layer.

2. The method of claim 1, wherein the release material comprises a urethane acrylic/silicone hybrid cured release coating on a polymeric film.

3. The method of claim 2, wherein the release coating has a thickness ranging from about 20 to 100 nanometers.

4. The method of claim 2, wherein the polymeric film is selected from the group consisting of polyethylene naphthalate (PEN) films, polyvinyl chloride (PVC) films, polymethylmethacrylate (PMMA) films, polycarbonate films, polyethylene terephthalate (PET) films, and polybutylenetherephthalate films.

5. The method of claim 1, wherein the protective web comprises a polypropylene film that is laminated to the dry film photoresist layer.

6. The method of claim 1, wherein the photoimageable liquid is applied to the moving web at a rate of from about 3 to about 50 meters per minute.

7. The method of claim 1, wherein the dry film photoresist layer is substantially devoid of air bubbles.

8. The method of claim 1, wherein the photoimageable layer is dried at a temperature ranging from about 110° to about 150° C.

9. A uniformly thick dry film photoimageable layer for a micro-fluid ejection head made by the method of claim 1.

10. The dry film photoimageable layer of claim 9 having an ultra-smooth imageable surface.

11. The dry film photoimageable layer of claim 10, wherein the ultra-smooth surface has a surface roughness (Ra) value of less than about 20 nanometers and a maximum peak to valley (Rt) value of less than about one micron.

12. A method of making a micro-fluid ejection head having a photoimageable nozzle plate, comprising:
applying a photoimageable thick film layer to a device surface of a substrate including fluid ejection actuators thereon;
imaging and developing the thick film layer to provide fluid flow features therein;
applying a photoimageable nozzle plate dry film layer made by a slot die coating method to the imaged and developed thick film layer; and
imaging and developing the dry film layer to provide nozzles therein for ejection of fluid therethrough.

13. The method of claim 12, wherein the slot die coating method comprises:
applying a photoimageable liquid to a moving web of conformal release material on a backing web to provide an ultra-smooth photoimageable layer on the backing web using a slot die coater, wherein the ultra-smooth layer on the conformal release material on the backing web has a coating thickness ranging from about 8 to about 25 microns with a thickness variation of no more than about one micron; and
drying the photoimageable layer on the web to provide a dry film photoresist layer.

14. The method of claim 13, wherein the conformal release material comprises urethane acrylic/silicone hybrid cured release coating on a polymeric film.

15. The method of claim 13, wherein the release coating has a thickness ranging from about 20 to 100 nanometers . . . .

16. The method of claim 13, wherein the backing web is selected from the group consisting of wherein the polymeric film is selected from the group consisting of polyethylene naphthalate (PEN) films, polyvinyl chloride (PVC) films, polymethylmethacrylate (PMMA) films, polycarbonate films, polyethylene terephthalate (PET) films, and polybutylenetherephthalate films.

17. The method of claim 13, wherein the photoimageable liquid is applied to the moving web at a rate of from about 3 to about 50 meters per minute.

18. The method of claim 13, wherein the dry film photoresist layer is substantially devoid of air bubbles.

19. The method of claim 13, wherein the photoimageable layer is dried at a temperature ranging from about 110° to about 150° C.

20. A micro-fluid ejection head made by the method of claim 12.
